(19) United States
(12) Patent Application Publication
(10) Pub. No.: US 2019/0309933 A1
(43) Pub. Date: Oct. 10, 2019

(54) SYSTEM FOR MOUNTING LED LIGHT MODULES

(71) Applicants: Sidney Howard Norton, Odessa, TX (US); Curtis Alan Roys, Fredericksburg, TX (US)

(72) Inventors: Sidney Howard Norton, Odessa, TX (US); Curtis Alan Roys, Fredericksburg, TX (US)

(21) Appl. No.: 16/282,039

(22) Filed: Feb. 21, 2019

Related U.S. Application Data
(60) Provisional application No. 62/635,362, filed on Feb. 26, 2018.

(51) Int. Cl. F21V 21/088; F21V 21/08

(52) U.S. Cl. CPC F21V 21/088; H01L 25/0753; F21V 21/0808

(57) ABSTRACT

An adaptor enables mounting of light-emitting diode (LED) modules onto pre-existing support elements, such as tubing, while avoiding problems with current mounting methods. The adaptor may be installed on the back side of any LED light module to enable a snap-on installation of the LED light module to tubular mounting hardware. The adaptor is held onto the tubular hardware by spring tension jaws designed into the manufacturing process of the adaptor. In the configurations disclosed adaptors can be manufactured to conform to any cross-sectional shape of the support element, including: square, triangular, rectangular, pentagonal, hexagonal, “I”-shaped, “L”-shaped, and round, over a wide cross-sectional dimension range. The adaptor may be mounted onto all industry-standard LED light modules with double-sided adhesive tape to allow quick and simple installation of the LED light module to any type or configuration of support element, which may be oriented horizontally, vertically or at various angles.

### CROSS-REFERENCE TO RELATED APPLICATION

The present application claims priority from U.S. Patent Application No. 62/635,362, filed on Feb. 26, 2018, which is hereby incorporated by reference.

### TECHNICAL FIELD

The present invention relates to a system for mounting light-emitting diode (LED) light modules.

### BACKGROUND

Common lighting includes incandescent lights, fluorescent lights and LEDs. Incandescent lights operate by flowing electricity through a filament inside a glass bulb. The filament heats up and glows, creating light. However, this technology creates a lot of heat. An incandescent light bulb loses 98% of its energy producing heat, making it quite inefficient. On Jan. 1, 2014, in keeping with a law passed by Congress in 2007, 40- and 60-watt incandescent light bulbs could no longer be manufactured in the U.S., because they failed to meet federal energy-efficiency standards. This policy was the final step in a gradual phase-out beginning in 2012 with 100-watt bulbs, then progressing to discontinuation of the 75-watt variety.

Fluorescent lights are low pressure mercury-vapor gas-discharge lamps that use fluorescence to produce visible light. An electric current in the gas excites mercury vapor which produces short-wave ultraviolet light that then causes a light-emitting phosphor coating on the inside of the bulb to glow.

Fluorescent lights are used as back lighting for signs. Fluorescent lamps are also found in residences, such as in kitchens, basements, or garages, in schools and in businesses because the cost savings when using fluorescent lamps tend to be significant when compared to the cost of incandescent light use. Disposal of fluorescent bulbs, which contain toxic mercury, is a problem.

The fastest-developing lighting technology today is the light-emitting diode (LED). Recent developments in LED technology have made LEDs more efficient and cheaper to use than both fluorescent bulbs and incandescent bulbs. A type of solid-state lighting, LEDs use a semiconductor to convert electricity directly into light, are often small in area (less than 1 square millimeter) and emit light in a specific direction, reducing the need for reflectors and diffusers that can trap light. LED's are also the most efficient lighting technology on the market. A light bulb's efficiency (also called luminous efficacy) is a measure of emitted light (lumens, lm) divided by power drawn (watts, W). A bulb that is 100 percent efficient at converting energy into light would have a luminous efficacy of 683 lm/W. To put this in context, a 60- to 100-watt incandescent bulb has a luminous efficacy of 15 lm/W, an equivalent compact fluorescent lamp (CFL) has a luminous efficacy of 73 lm/W, and current LED-based replacement bulbs on the market range from 70 to 120 lm/W with an average luminous efficacy of 85 lm/W.

LED light modules and strip lighting have been in existence for several years. A current trend is to retrofit incandescent and fluorescent lighting with energy and environmentally-friendly LED technology. Such a system is described, for example, in U.S. Pat. Pub. No. 20170023186 for “Method and Assembly for Replacing Fluorescent Lights”. In a retrofit replacement for a fluorescent light, one or more LED modules are typically mounted onto a support, such as an aluminum tube, and end caps configured to fit into the fluorescent light sockets are installed on the ends of the support. Power is provided to the LED modules from a power supply through one or more of the end caps or through a wire that runs from the power supply to the LED modules without going through the end caps.

LED light modules are typically manufactured having double-sided adhesive tape on the backside for mounting the module onto the surface of a support and having holes for screws for mounting the module onto the support. The double-sided adhesive tape requires a clean surface to adhere to. The square aluminum stock tubes from which the supports are made in a sign shop often have on their surfaces an oily residue, which can cause the adhesive on the tape to fail to hold the LED light module to the aluminum tubing, particularly when temperatures rise in a sign cabinet. An oil film may persist even after cleaning. The adhesive loses adhesion due to the heat and oily surface and the modules may fall off the aluminum tubing. This problem dictates the additional use of fasteners (screws) to securely hold each module in place, which requires drilling screw holes at the desired positions in the support and is time consuming.

Thus, it would be beneficial to enable easier, faster and more convenient mounting of LED light modules to obtain these advantages of high luminous efficacy LED lighting in place of older, less efficient lighting methods.

### SUMMARY

A system for mounting LED light modules for mounting LED light modules in an enclosure such as a sign cabinet is provided. The system includes a mounting adapter, some embodiments of which are referred to as a LUMA (LED Universal Mounting Adaptor), for mounting an LED light module onto a support. Also described is an LED light assembly using the mounting adapter, a method of mounting an LED light module onto a support element, a kit containing the mounting adapter, and a bracket for providing additional support for the LED module.

Adaptors can be installed on the back side of any LED light module to enable the simple snap-on installation of the LED light module to support elements, such as tubular mounting hardware (“tubing”). The LUMA holds itself firmly on the support element by spring tension jaws, the springiness of which is typically designed into adapter during the manufacturing process. The system may also include brackets that mount onto the LED mounting assembly that snap on to an additional support member, thereby providing support for the support on which the LED module is directly mounted.

The foregoing has outlined rather broadly the features and technical advantages of the present invention in order that the detailed description of the invention that follows may be better understood. Additional features and advantages of the invention will be described hereinafter. It should be appreciated by those skilled in the art that the conception and specific embodiments disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more thorough understanding of the present invention, and advantages thereof, reference is now made to the following descriptions taken in conjunction with the accompanying drawings, in which:

FIG. 1 is an isometric view of an LED light assembly with an LED mount being attached.

FIG. 2 is an isometric view of the LED light assembly of FIG. 1 after attachment of the LED mount.

FIG. 3 an isometric view of the LED light assembly of FIG. 2 after attachment to a support element such as a tube.

FIG. 4 is an end view of the LED light assembly of FIG. 3.

FIG. 5 is an isometric view of an LED light assembly with alternating orientations of the LED mounts on a support element.

FIG. 6 is a side view of the LED light assembly of FIG. 5.

FIG. 7 is an isometric view of an LED light assembly with a horizontal support brace design shown during attachment of a bracket.

FIG. 8 is an isometric view of the LED light assembly of FIG. 7 after attachment of the bracket.

FIG. 9 is an isometric view of the LED light assembly of FIG. 8 after mounting on a first support element.

FIG. 10 is an isometric view of the LED light assembly of FIG. 9 after mounting on a second support element.

FIG. 11 is a top view of the LED light assembly of FIG. 10.

FIG. 12 is an isometric view of the bracket.

FIG. 13 is an isometric view of an LED light assembly with a molded jaw.

FIG. 14 is an isometric view of an LED light assembly with alternating orientations of the LED mounts on a support element.

FIG. 15 is an end view of the LED light assembly of FIG. 13.

FIG. 16 is an end view of the LED light assembly of FIG. 14.

FIG. 17 is an isometric view of an LED mount having three-leg jaws.

FIG. 18 is a side view of the LED light assembly of FIG. 17.

FIG. 19 is an isometric view of an LED light assembly mounted onto a support element with alternating orientations of the LED mounts.

FIG. 20 is an isometric view of an LED mount having three-leg jaws for interlocking mounting onto a support element.

FIG. 21 is a side view of the LED light assembly of FIG. 20.

FIG. 22 is an isometric view of the assembly process of the LED light assembly of FIG. 20 onto a support element with interlocking mounting of the LED mounts.

FIG. 23 is an isometric view of the LED light assembly of FIG. 22 after completion of attachment of the LED mounts onto the support element.

FIG. 24 is an isometric view of the assembly process for a two-light LED mount.

FIG. 25 is an isometric view of the two-light LED mount of FIG. 24 after completion of mounting two LED light modules.

FIG. 26 is an isometric view of a multiple LED light assembly as in FIG. 25 attached to a support element.

FIG. 27 is an end view of the LED light assembly of FIG. 26.

FIG. 28 is a flow chart for construction of the LED light assembly of FIGS. 1-6.

FIG. 29 is a flow chart for construction of the LED light assembly of FIGS. 7-12.

FIG. 30 is a flow chart for construction of the LED light assembly of FIGS. 20-23.

FIG. 31 shows another embodiment of an LED mount.

FIG. 32 shows an isometric view of LED mount of FIG. 31.

FIG. 33 shows a top view of LED mount of FIG. 31.

FIG. 34 shows a top view of LED mount of FIG. 31.

FIG. 35 shows a front elevation of LED mount of FIG. 31.

FIG. 36 shows another embodiment of a bracket.

FIG. 37 shows a rear elevation of the bracket of FIG. 36.

FIG. 38 shows a front elevation of the bracket of FIG. 36.

FIG. 39 shows a bottom view of the bracket of FIG. 36.

FIG. 40 shows a left elevation of the bracket of FIG. 36.

FIG. 41 shows a right elevation of the bracket of FIG. 36.

### DETAILED DESCRIPTION

Adaptors are disclosed which can be installed on the back side of any LED light module to enable the simple snap-on installation of the LED light module to support elements, such as tubular mounting hardware (“tubing”). In many embodiments, the LUMA (LED Universal Mounting Adaptor) holds itself firmly on a support element by spring tension jaws. The springiness is typically designed into the jaws and occurs as a result of the jaw design and manufacturing. The term “spring tension” and similar terms as used herein does not imply the use of a separate spring element, but can be the result of the springiness of the material from which the adapter is formed. Because the LUMA is typically held in place on the support by friction, the LUMA can also be readily removed, for example, to replace a faulty LED light module. It can also be positioned and/or repositioned at any position along the support to position of the light module where required. The LUMA is preferably made from any material that is sufficiently elastic such that the LUMA will clamp onto a support with sufficient force to be immobile in use. The material is preferably also sufficiently flexible, and the spring tension not so grate, so that that the adapter can be removed or repositioned as required. Suitable materials include plastics or other polymers, including thermoplastics, such as acrylonitrile butadiene styrene (ABS) and elastomers. The LUMA is also preferably made from a material that bonds well to the adhesive used on the LED light modules. A LUMA could also be made of metal or other material. Whatever material is chosen, the wall thickness of the material is selected to provide the correct balance between clamping force and ease of mounting and removing. In some embodiments, the jaws have a “toe-in” angle, that is, the jaws angle slightly towards each other toward their distal ends. The frictional force between the adapter and the support is determine, therefore, by the material properties, such as the Young's modulus, of the adapter, the wall thickness, and the toe-in angle. The frictional force between the adapter and the support will also be affected by the material from which the support is made. Various mechanical geometries of the adapter will also affect the ease of mounting and removal of the adapter, as well as how well the adapter adheres to the support. For example, projections at the end of the jaws can trap the support between the jaws. Angles surfaces at the end of the jaws can facilitate separating the jaws as the adapter is pushed onto the support.

Some embodiments could use a biasing device, such as a spring, to hold the jaws closed, rather than using the natural springiness of the LUMA material. The LUMA can be manufactured to conform to support elements having any cross-sectional shape, for example, square, triangular, rectangular, pentagonal, hexagonal, “I”-shaped, “L”-shaped, and round. Industry-standard LED light modules with double-sided adhesive tape can be mounted onto the LUMA snap on adaptor to allow quick and simple installation of the LED light module to any type or configuration of support element. The bonding process of the adhesive to the adapter is preferably permanent, immediately effective, and cannot be readily removed. That is, the LED is preferably permanently bonded to the adapter using an adhesive, while the adapter is removably mounted to the support without adhesive. In some embodiments, the LUMA and the LED light module are manufactured as one piece and the LUMA becomes an integral part of the LED light module. That is, the LUMA can be manufactured (typically molded) as an integral part of the LED light module. Manufacturing the LED light module and the LUMA as a one-piece integral unit, eliminates the need to attach the LUMA to the LED light module with adhesive. This embodiment eliminates the need to attach the LUMA to the module and eliminates the need for any type of double stick adhesive to mount the LED light module.

In other embodiments, the adapter snaps over the LED light module, trapping it against the support in a pocket formed in the adapter. The pocket extends over a portion of the LED light module to hold it against the support, while having an opening exposing the LEDs to allow the light from the LED to shine out from the adapter. In other embodiments, the LUMA provides a snap-on support to prevent the horizontally installed LED light sticks from sagging in the center by snapping onto a vertical support as well as onto the horizontal LED support. The LED industry has struggled for years to find a simple and functional method to attach modules to aluminum or other materials used in LED light stick replacement of fluorescent fixtures.

Embodiments differ from customary mounting techniques for LED light modules onto aluminum tubes or other types of support element. Embodiments enable any size LED light module to be easily installed onto any support element size or configuration. The LUMA are manufactured in several configurations and are designed to be easily mounted on any LED light module. After attachment of the LUMA to the LED light module, the LED light module may be snapped into place on the support element and the assembly may then be installed into a sign cabinet, lighting fixture, or other enclosure. This will enable the end user to quickly and easily install LED lighting modules on any size, dimension or configuration of new or retrofit mounting hardware to replace fluorescent tubes. The simple installation of LED light modules for residential or commercial lighting fixtures can reduce electrical power consumption world-wide.

LED Light Assembly with a Tape-On Mounting Adaptor in a Unidirectional Mounting Configuration

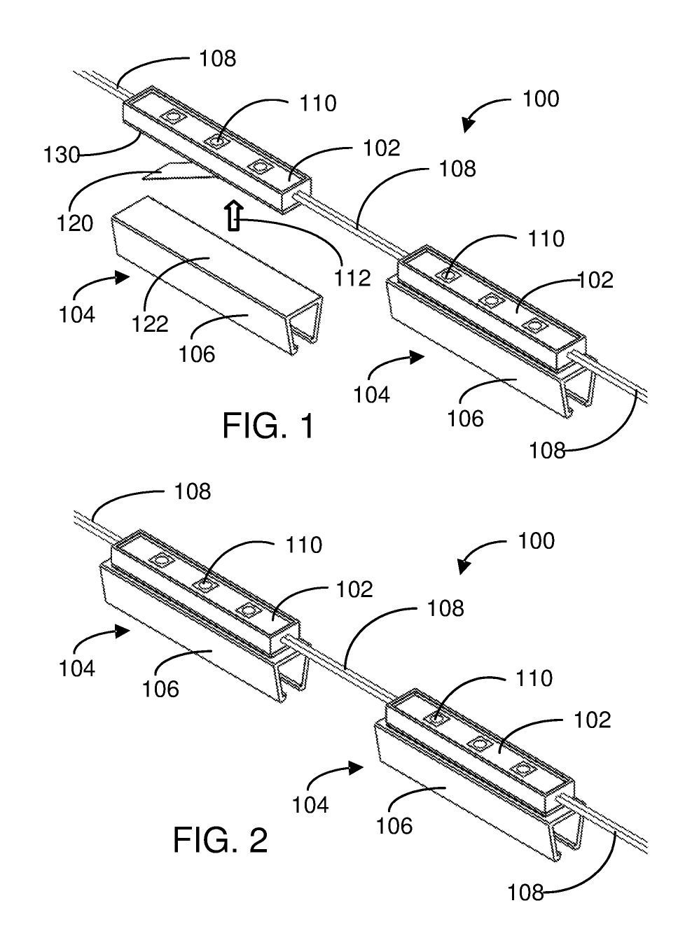

FIGS. 1-4 illustrate an LED light assembly 100 having a tape-on mounting adaptor with the LED lights in a unidirectional mounting configuration.

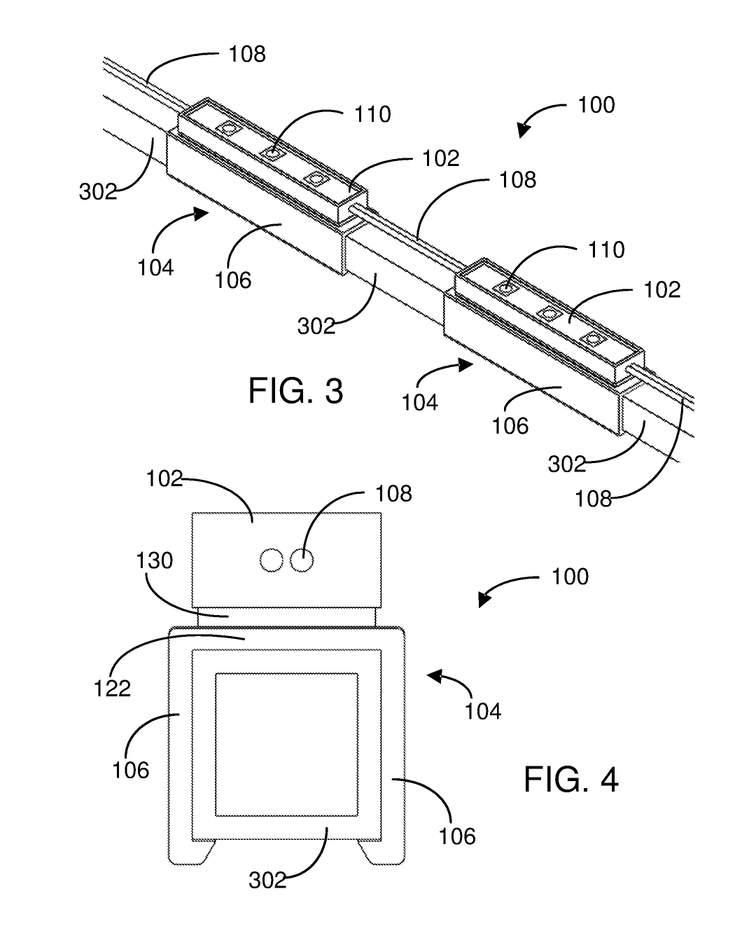

FIG. 1 is an isometric view of an LED light assembly 100 with an LED mount 104 (also referred to as a “LUMA”) attached to an LED light module 102 and having jaws 106 for attaching to a support. Double-sided adhesive tape 130 has one sticky side pre-attached to the back (i.e., the side opposite from the LEDs 110) of LED light module 102, with the opposite sticky side initially covered by a tape liner 120. After manual removal of tape liner 120 (this peeling-off operation is shown in progress in FIG. 1), LED mount 104 may be moved (attachment motion 112) to place LED attachment surface 122 in contact with double-sided adhesive tape 130, which has a sticky surface now exposed after removal of tape liner 120. Multiple LED light modules 102 may be interconnected by LED wires 108. The LED wires 108 may be connected to an LED power supply. Each LED light module 102 may comprise one or more LEDs 110. The function of jaws 106 is shown in FIG. 3. FIG. 2 is an isometric view of LED light assembly 100 after attachment of LED mount 104. In some embodiments, other forms of attachment between LED light module 102 and LED mount 104 may be employed, such as liquid glue, or a mechanical snap connect connection comprising, for example, a flexible pin-like structure in one part fitting into a hole in the other part. The pin-like structure may be part of the LED mount 104 or part of the LED light module 102, in which cases the hole would be part of the LED light module 102 or part of the LED mount 104, respectively. The first jaw 106 may be attached at a first edge to a first edge of the attachment surface 122, wherein the first jaw is approximately at a right angle with respect to the attachment surface 122. The second jaw 106 may be attached at a first edge to a second edge of the attachment surface 122, the second edge of the attachment surface 122 being approximately parallel to and spaced apart from the first edge of the attachment surface 122, wherein the second jaw 106 is approximately parallel to the first jaw 106 and extending in the same direction from the attachment surface 122 as the first jaw 106. Jaws with a “tow in”, such as the jaws 106 shown in FIG. 1, are still considered to be “substantially parallel” or “approximately parallel” as those terms are used herein.

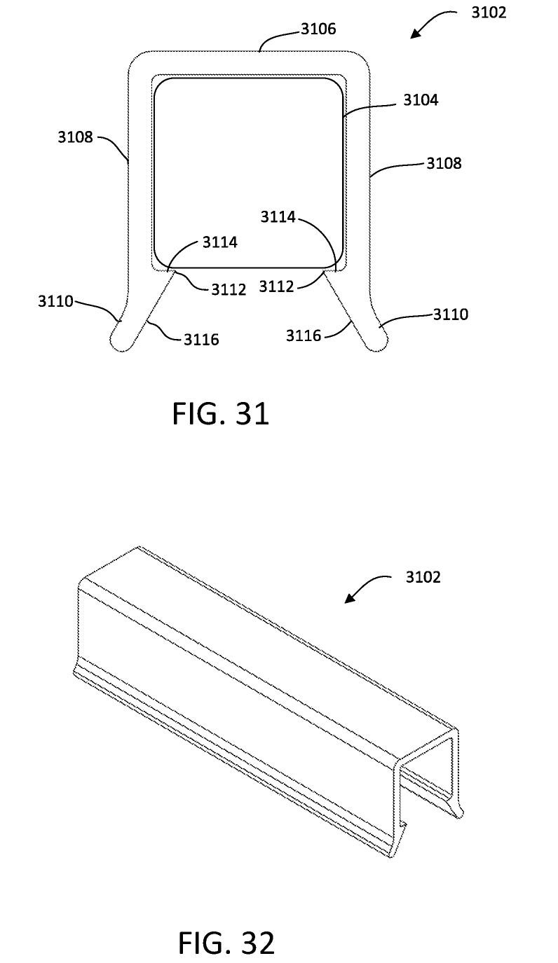

FIG. 31 shows a right elevation of another embodiment of an LED mount. LED mount 3102 is shaped to mate with an LED support 3104 (in this example, a square tube) to which the LED mount 3102 is attached. A top portion 3106 and two side portions (jaws) 3108, which together form a shape complementary to the shape of support 3104 in order to mate with the support 3104. Extending from the distal ends of side portions 3108 are tabs 3110 and projections 3112. Projections 3112 define ledges 3114 that trap LED support 3104. Tabs 3110 have inner facing surfaces 3116 that are angled outward away from the each other as they extent from side portions 3108. When LED mount 3102 is pressed onto LED support 3104, LED support 3104 presses against angled surfaces 3116 to spread the side portions 3108 wide enough so that support 3104 can slide past projections 3112. After support 3104 is completely past projection 3112, side portions 3108 move back together and projections 3112 capture support 3104 on ledges 3114. Tabs 3110 can be used to manually spread sides 3108, for example, by a user's thumbs, to reduce friction to allow the LED mount 3102 to be slid along the support 3104. Tabs 3110 can be used to manually spread sides 3108 to remove LED mount 3102 from support 3104. This allows substitution of one LED mount 3102 with a mounted LED module for another LED mount 3102 with a different LED module. The LED mount 3102 shown in FIG. 31 has little or no toe-in. The projections 3112 can provide additional friction between LED mount 3102 and support 3104. The friction between the LED adapter and the support is preferably sufficient to prevent the LED adapter from moving on the support during use, while not so great as to prevent a user from easily removing the adapter. The friction to maintain the LED mount on the support in any embodiment can be provided by contact anywhere between the two structures, including contact on the sides, contact on the bottom and contact on the top.

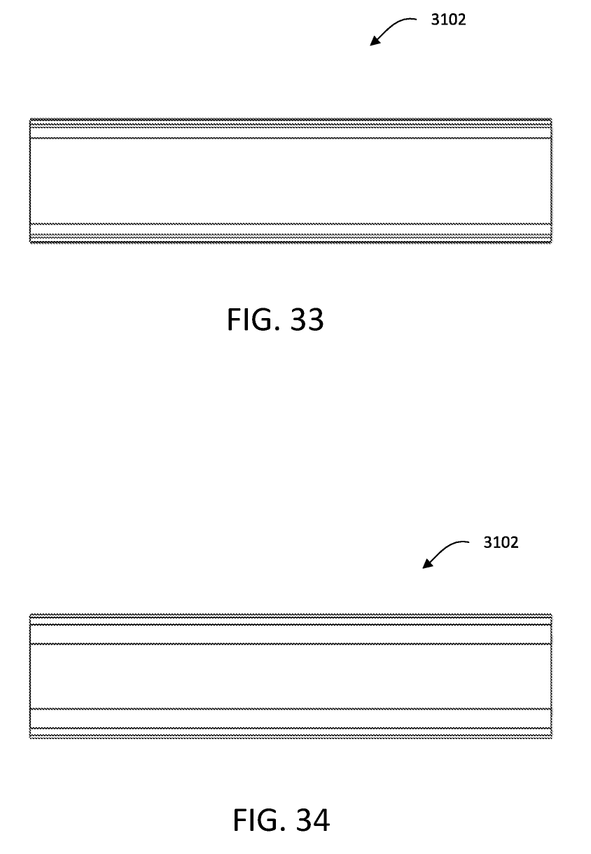

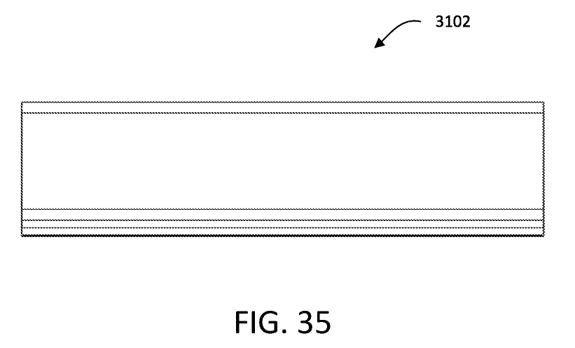

FIG. 32 shows an isometric view of LED mount 3102. FIG. 33 shows a top view of LED mount 3102, and FIG. 34 shows a top view of LED mount 3102. FIG. 35 shows a front elevation of LED mount 3102. A left elevation would look the same as the right elevation shown in FIG. 31 and a rear elevation would look the same as the front elevation shown in FIG. 35.

FIG. 3 is an isometric view of the LED light assembly 100 of FIG. 2 after attachment to a support element 302. Attachment is preferably effected without the need for glue, adhesives, screws or bolts, through the spring-clamping action of opposing jaws 106 as shown in FIG. 3, although the use of other attachment means is not precluded. The edges of jaws 106 may comprise inward-facing catches on the distal edges (i.e., the catches face each other), wherein each catch preferably has a beveled “lead” to facilitate spreading apart of jaws 106 as LED mount 104 is pressed onto support element 302. As shown in FIGS. 1 and 2, jaws 106 have a normal (i.e., unsprung) position which is angled inwards such that the spacing between the lower ends (i.e., the ends of jaws 106 away from LED attachment surface 122) are closer together than the expected dimension of the support element 302 onto which LED mount 104 is to be attached. Thus, the operation of pressing LED mount 104 onto support element 302 may spread jaws 106 apart while also inducing a clamping force between jaws 106 and support element 302 which, along with the hooked and beveled lower ends of jaws 106, will serve to securely hold LED mount 104 onto support element 302. LED mount 104 is preferably made of a material, such as ABS, that has sufficient elasticity that the jaws can be readily spread apart to pass over the support element and then will spring back into place with sufficient force to hold the LED mount fixed to the support. The wall thickness is preferably 0.060 or 0.070, which is sufficiently thick to clamp onto the support while sufficiently springy to allow for removal in order to reposition or replace an LED mount. In some embodiments, a relief radius is formed in the interior corner between each jaw and the top portions that the LED support element will fit within the LED mount without interference. The LED mount 104 is preferably made of a material which can form a strong bond with the adhesive used to attach the LED light module to the LED mount. For example, the LED mount 104 could be made from plastic or from metal.

After attachment of one or more LED light modules 102 onto support element 302, LED wires 108 may be either stretched taught between neighboring LED light modules 102 as shown, or (if LED light modules 102 are more closely-spaced) LED wires 108 may have some slack (not shown). Typically, multiple LED light modules 102 may be pre-connected by LED wires 108 with pre-set wire lengths between neighboring LED light modules 102—these pre-set wire lengths may determine the maximum spacing between LED mounts 104 after attachment to support element 302. Once the LED light mount is clamped onto the support 302, it can be repositioned by sliding or it can be removed. The LED mounts can be molded as a single piece, or can be extruded and cut to length.

FIG. 4 is an end view of LED light assembly 100, illustrating the inter-relationships between LED light module 102, double-sided adhesive tape 130 and the LED attachment surface 122, as well as the clamping mechanism between jaws 106 and support element 302.

In some embodiments, the support element may comprise insulating end caps, the insulating end caps operable to fit within the sockets of a fluorescent light cabinet.

LED Light Assembly with a Tape-On Mounting Adaptor in a Bi-Directional Mounting Configuration

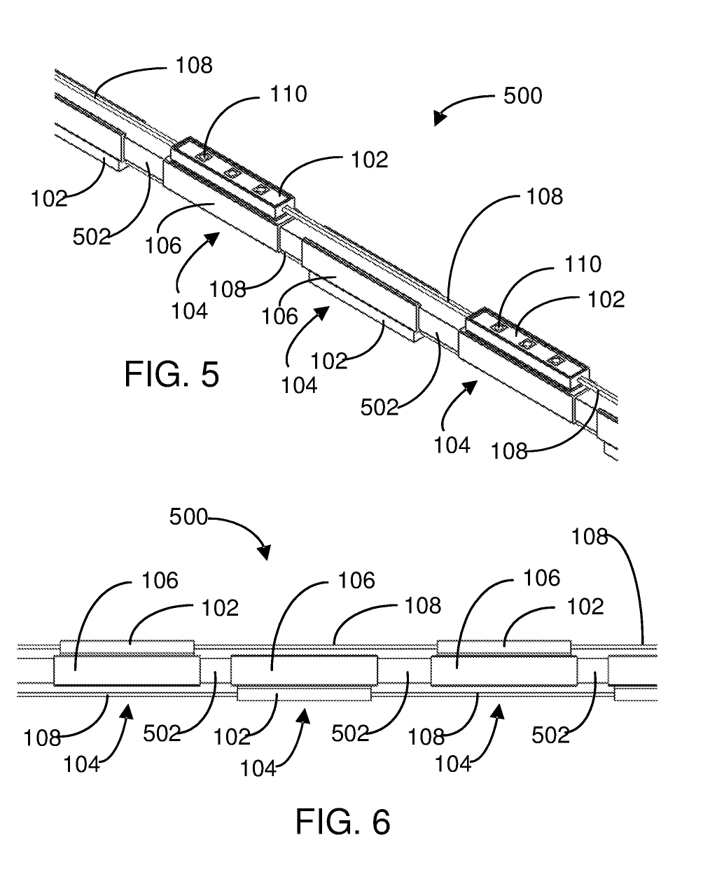

FIGS. 5 and 6 illustrate a variant on the LED light assembly 100 of FIGS. 1-4, in which alternating LED mounts 104 are mounted in opposite (i.e., 180° different orientations) directions to facilitate a wider field of illumination by LED light assembly 500.

FIG. 5 is an isometric view of LED light assembly 500 with alternating orientations of the LED mounts 104 on a support element 502. As shown, now the lengths of LED wires 108 determine the spacing between LED mounts 104 which have another LED light module 102 mounted in the opposite direction between them, thus typically in this LED light assembly, the lengths of LED wires 108 may need to be longer than in FIGS. 1-4. In some wiring configurations, the control of power (through a first set of LED wires 108) to the LED light modules 102 facing upwards in FIG. 5 may be separate from the control of power (through a second set of LED wires 108) to the downward-directed LED light modules 102 in FIG. 5, enabling illumination to be provided only upwards, only downwards, or both upwards and downwards, depending on the illumination requirements at any one time.

FIG. 6 is a side view of the LED light assembly of FIG. 5, illustrating more clearly the electrical connections of LED wires 108 between the upward-directed LED light modules 102, and the (potentially) separate electrical connections of LED wires 108 between the downward-directed LED light modules 102 mounted facing in opposite directions on support element 502.

LED Light Assembly with Multiple Support Elements

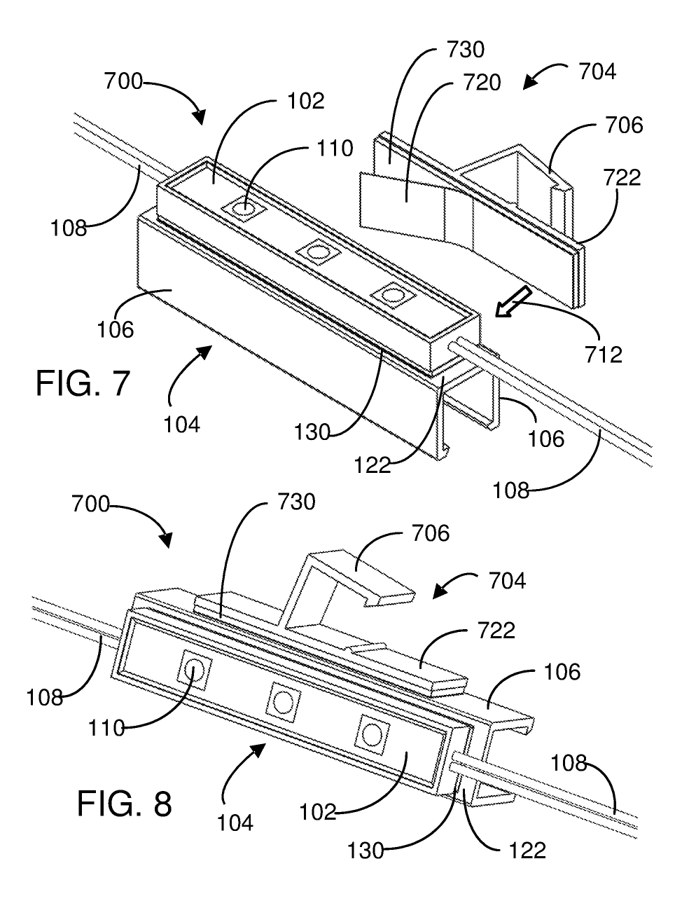

FIGS. 7-12 illustrate an LED light assembly 700 operable for a simultaneous clamp attachment to multiple support elements. The two support elements may have a generally orthogonal inter-relationship, wherein, for example, a first support element may be horizontal, and a second support element may be vertical, however other orientations of the two support elements (also having a generally orthogonal inter-relationship) fall within the scope of the disclosure.

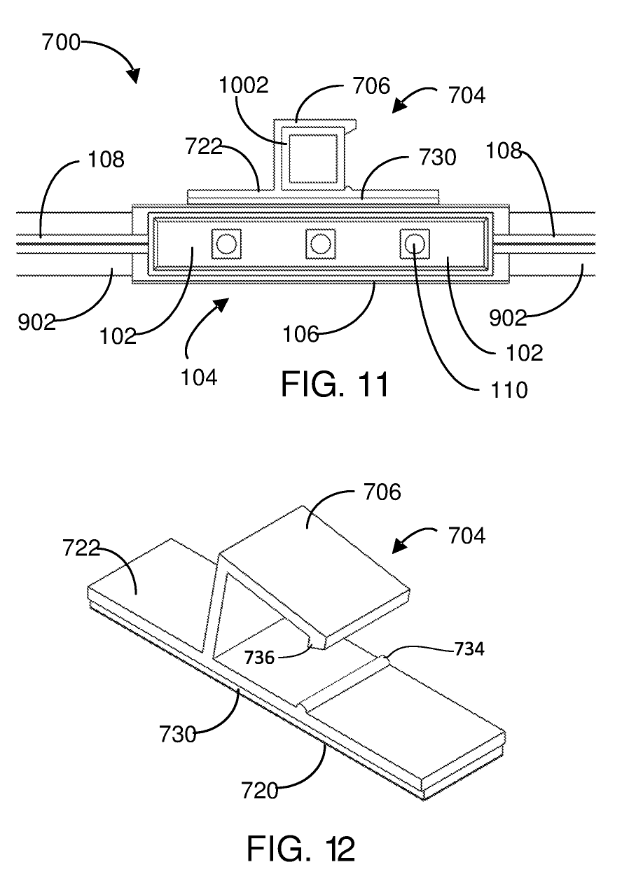

FIG. 7 is an isometric view of an LED light assembly 700 shown during attachment of a bracket 704. Double-sided adhesive tape 730 has one sticky side pre-attached to bracket 704 at a bracket attachment surface 722, with the opposite sticky side initially covered by a tape liner 720. After manual removal of tape liner 720 (this peeling-off operation is shown in progress in FIG. 7), Bracket 704 may be moved (attachment motion 712) to place jaw 106 (on the far side of LED mount 104 in FIG. 7) in contact with double-sided adhesive tape 730, which has a sticky surface now exposed after removal of tape liner 720. The function of jaw 706 is shown in FIGS. 10 and 11. FIG. 8 is an isometric view of LED light assembly 700 after attachment of bracket 704.

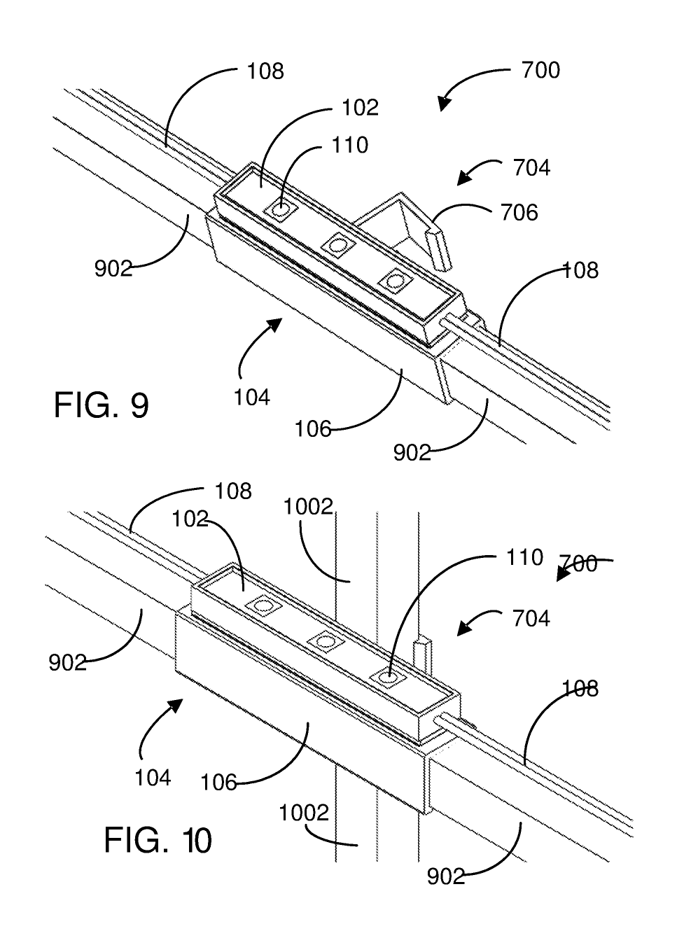

FIG. 9 is an isometric view of LED light assembly 700 after mounting on a first support element 902 using jaws 106, similar to the mounting method shown in FIGS. 3 and 5. FIG. 10 is an isometric view of LED light assembly 700 in FIG. 9 (mounted on first support element 902) after mounting on a second support element 1002. This embodiment thus serves to interconnect first support element 902 with second support element 1002 in addition to the function of providing a mounting structure for LED light modules 102.

FIG. 11 is a top view (assuming that first support element 902 is horizontal and second support element 1002 is vertical) of the LED light assembly 700 of FIG. 10, illustrating the attachment to support element 1002 enabled by jaw 706, as well as the attachment to support element 902 enabled by jaws 106. In this configuration, LEDs 110 will direct illumination generally upwards (or downwards). FIG. 12 is an isometric view of bracket 704. Jaw 706 includes a projection 736 which, together with rounded bump 734, traps support 1002 into bracket 704. Rounded bump 734 and the angle on projection 736 allows the support to enter between jaw 706 and attachment surface 722 and snap into place. The “toe-in” angle between attachment surface 722 and jaw 706 provides sufficient pressure on support 1002 to hold the bracket 704 firmly in place on support 1002, yet not so much pressure that removable is unduly difficult. The preferred toe-in angle will depend on the springiness of the material, which will depend on the type of material and on the wall thickness.

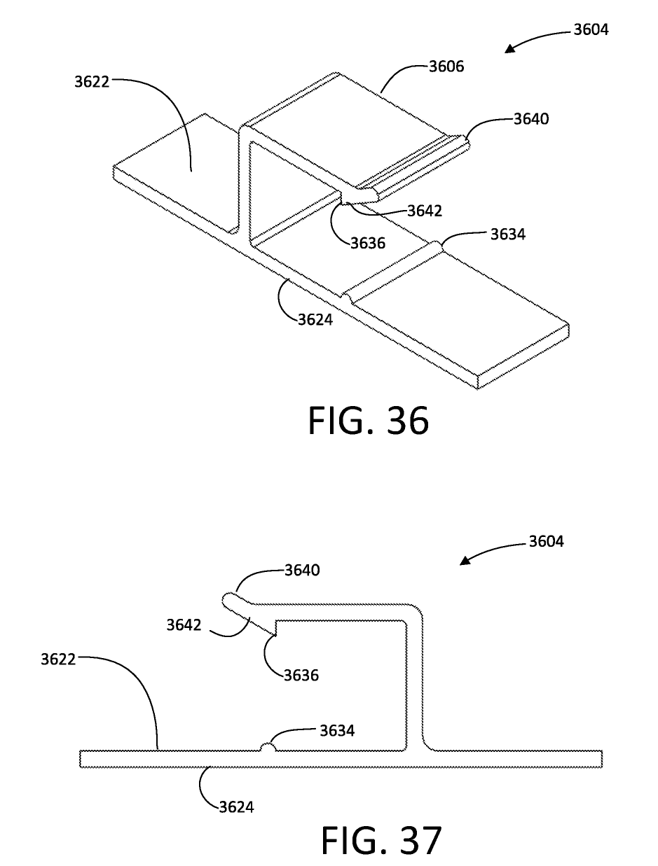

FIG. 36 shows another embodiment of a bracket 3604 that can provide support to a horizontal LED support to keep it from sagging by attaching it to a vertical support. Bracket 3604 includes a jaw 3606, an attachment portion 3622, a projection 3636 that extends from jaw 3606, and a bump 3634, all of which are similar to the corresponding parts of bracket 702. Bracket 3604 further includes a tab 3640 having an angled surface 3642 that angles away from attachment portion 3622. When bracket 3604 is pressed against support 1002 (FIG. 10), angles surface 3642 forces jaw 3606 open, allowing support 1002 to enter the bracket 3604 and be trapped between projection 3636 and bump 3634. A user can lift tab 3640 to expand the opening between jaw 3606 and surface 3622, allowing the bracket 3604 to be removed from support 1002 or to slide to be repositioned along support 1002. Bracket 3604 includes an attachment surface 3624 on the bottom of attachment portion 3622. Bracket 3604 preferably also include on attachment surface 3624 a double-sided tape (not shown) for attaching to an LED mount, such as mount 104 (FIG. 7) or mount 3102 (FIG. 31) The embodiment shown in FIG. 36 has little or no toe-in. The projection 3636 and bump 3634 maintain support 1002 between the bracket 3604 and the support.

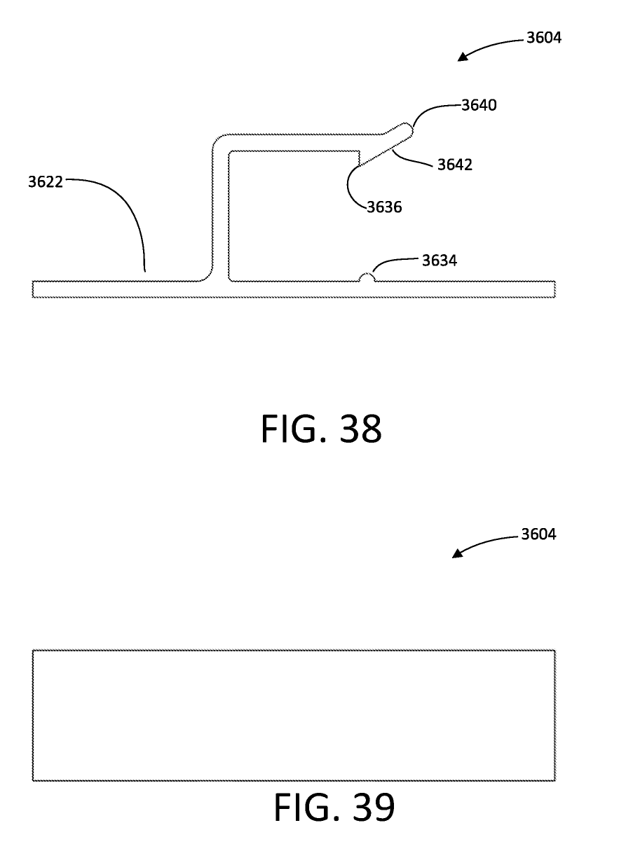

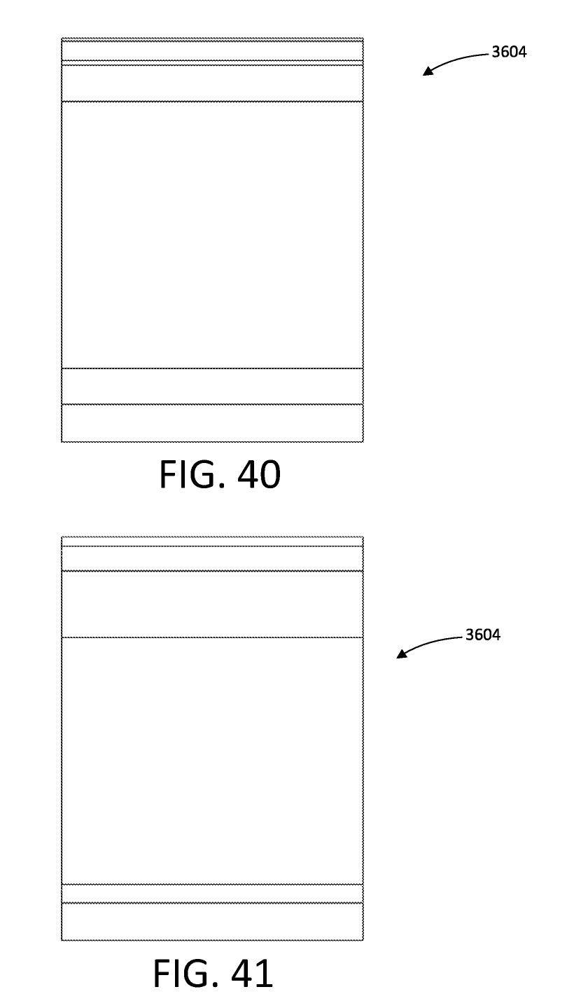

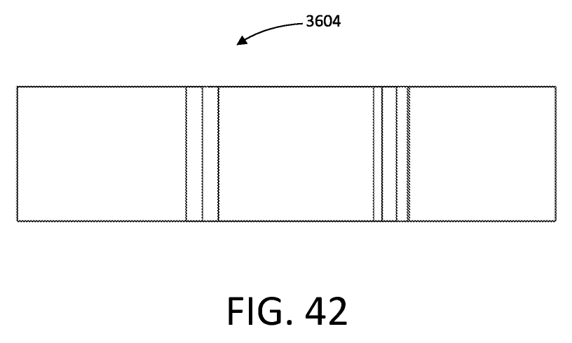

FIG. 37 shows a rear elevation of bracket 3604. FIG. 38 shows a front elevation of bracket 3604. FIG. 39 shows a bottom view of bracket 3604. FIG. 40 shows a left elevation of bracket 3604 and FIG. 41 shows a right elevation of bracket 3604.

LED Light Assembly with Molded-in Jaws

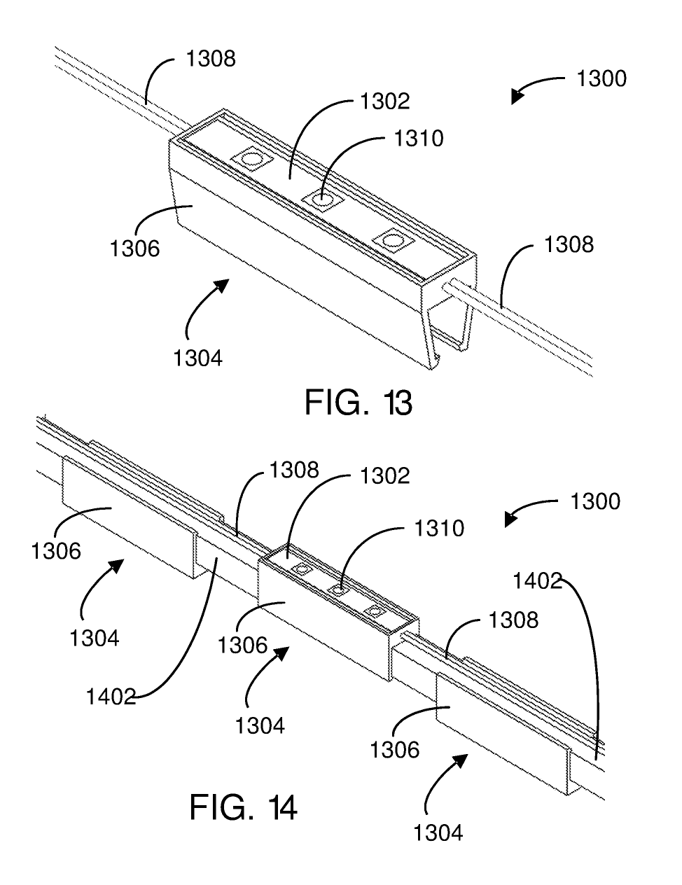

FIGS. 13-16 illustrate an LED light assembly 1300 with two molded-in jaws 1306, wherein LED mount 1304 may be a single molded part comprising an LED light module 1302 with LEDs 1310. Alternatively, LED light module 1302 may a separate component retained within a pocket at the top of LED mount 1304 by an upper shape of LED mount 1304 such as a flexible retaining edge (not shown). That is, an LED mount snaps onto a support and traps an LED module between the LED mount and the support, with the LED positioned at an aperture in the LED mount to allow the emission of light. That is, the LED module fits in a well in the LED mount, and when the LED mount is snapped onto the support, the LED module is retained in the well. LEDs 1310 will emit light in a generally upwards direction with power supplied by LED wires 1308.

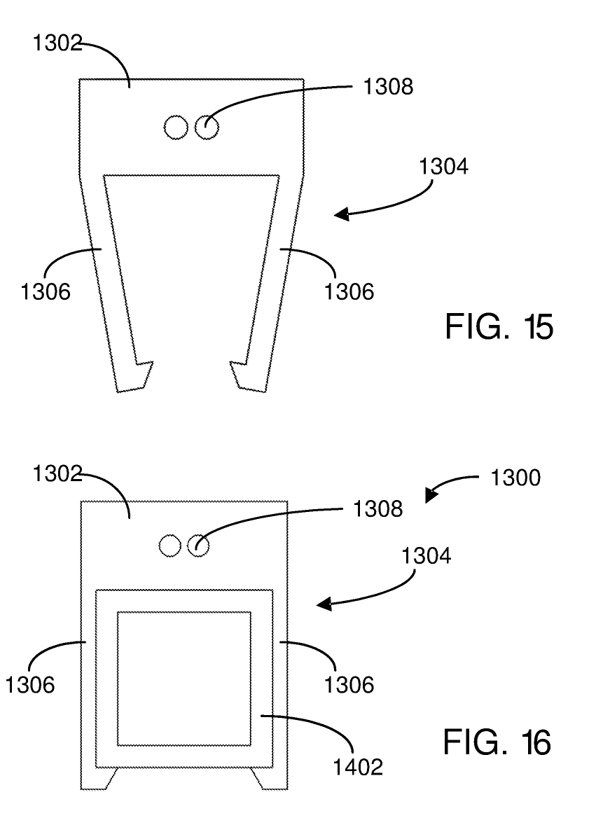

FIG. 13 is an isometric view of LED light assembly 1300 with a molded jaw design. FIG. 14 is an isometric view of an LED light assembly with alternating orientations of the LED mounts 1304 on a support element 1402—this arrangement of LED mounts 1304 may enable illumination upwards, downwards, or both upwards and downwards, similarly to the operation of LED light assembly 500. LED mounts 1304 may also be attached in a unidirectional configuration (as in LED light assembly 100). FIG. 15 is an end view of LED mount 1304 and FIG. 16 is an end view of LED light assembly 1300, illustrating the clamping mechanism of jaws 1306 onto support element 1402.

LED Light Assembly with Three-Leg Jaws

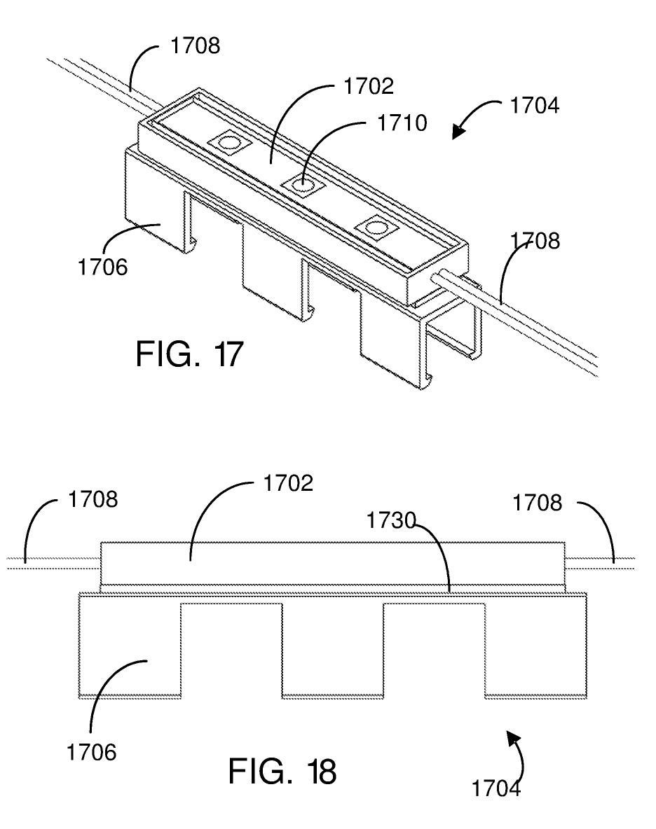

FIGS. 17-19 illustrate an LED light assembly 1900 having a tape-on jaw 1706 with the lights in a unidirectional mounting configuration, wherein jaw 1706 has a three-leg configuration and in which the gaps between neighboring legs may be at least as wide as the widths of the legs in the jaw.

FIG. 17 is an isometric view of an LED mount 1704 having a three-leg jaw 1706. LEDs 1710 are powered by LED wires 1708 which may interconnect between neighboring LED light modules 1702. FIG. 18 is a side view of LED mount 1704, illustrating the positional relationship between the legs of jaws 1706 and LED light module 1702 (compare with FIG. 21). Double-sided adhesive tape 1730 has one sticky side pre-attached to the back (i.e., the side opposite from the LEDs 110) of LED light module 1702, with the opposite sticky side initially covered by a tape liner (not shown). After manual removal of the tape liner, LED mount 1704 may be moved to place an LED attachment surface (not shown) in contact with double-sided adhesive tape 1730, which has a sticky surface now exposed after removal of the tape liner.

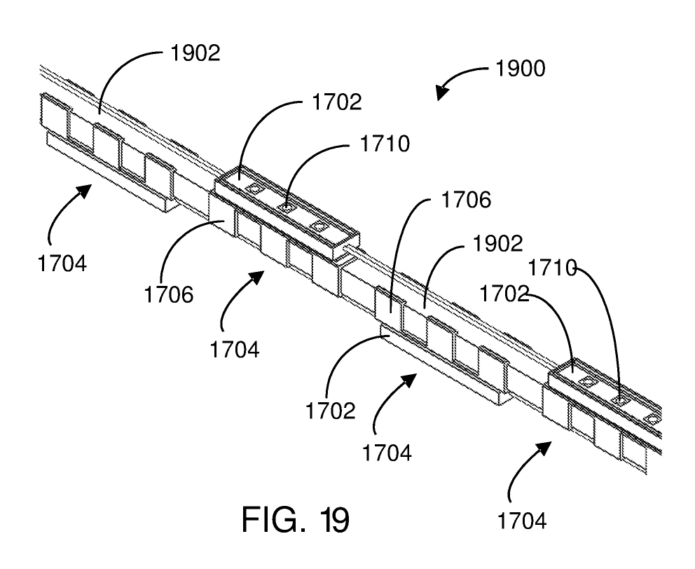

FIG. 19 is an isometric view of LED light assembly 1900 mounted onto a support element 1902 with alternating orientations of the LED mounts 1704—this arrangement of LED mounts 1704 will enable illumination upwards, downwards, or both upwards and downwards, similarly to the operation of LED light assemblies 500 or 1300. LED mounts 1704 may also be attached in a unidirectional configuration (as in LED light assembly 100).

LED Light Assembly with Interlocking Jaws

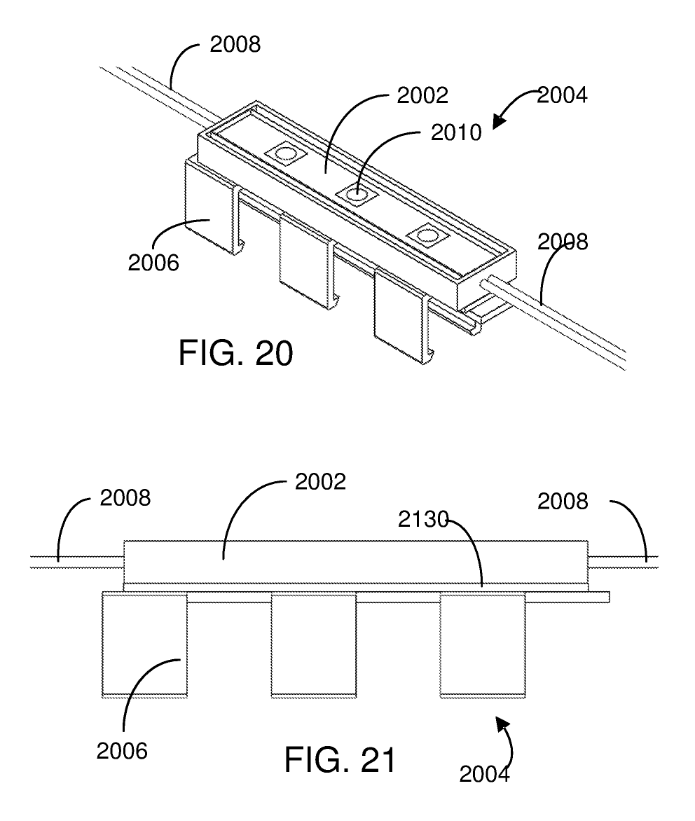

FIGS. 20-23 illustrate an LED light assembly 2200 having a tape-on jaw 2006 with the lights in a bidirectional mounting configuration and wherein the jaws 2006 have an interlocking three-leg configuration.

FIG. 20 is an isometric view of LED mount 2004 having a three-leg jaw 2006 for interlocking mounting onto a support element (compare the offset configuration of the legs in jaw 2006 with the symmetrical legs of jaw 1706 in FIG. 18). FIG. 21 is a side view of LED mount 2004, illustrating double-sided adhesive tape 2130 attaching LED light module 2002 to LED mount 2004. LEDs 2010 are powered by LED wires 2008.

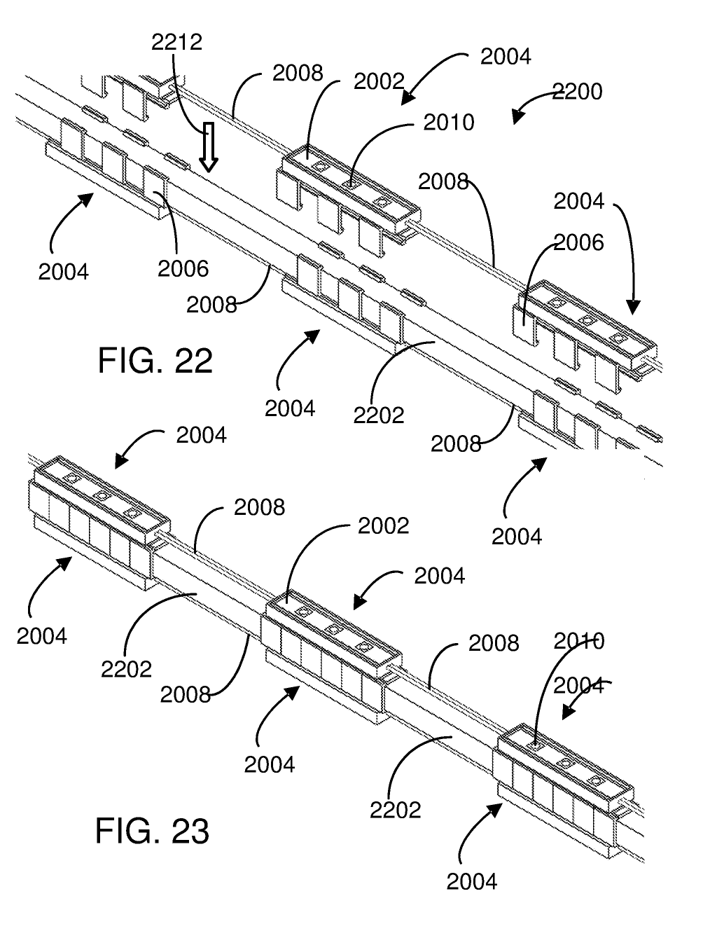

FIG. 22 is an isometric view of the assembly process of LED light assembly 2200 onto support element 2202 with interlocking mounting of LED mounts 2004—the offset configuration of the legs in jaws 2006 facilitates the interlocking of LED mounts 2004 attaching from opposite sides of support element 2202 as shown. Attachment motion 2212 shows the direction of motion of an upper LED light assembly 2200 onto support element 2202 where a lower LED light assembly 2200 has previously been attached. FIG. 23 is an isometric view of LED light assembly 2200 after completion of assembly. As for LED light assemblies 500 and 1300, upward, downward, or upward and downward illumination is possible if the upper and lower sets of LED light modules 2002 are wired separately.

LED Light Assembly with Two-Light Modules

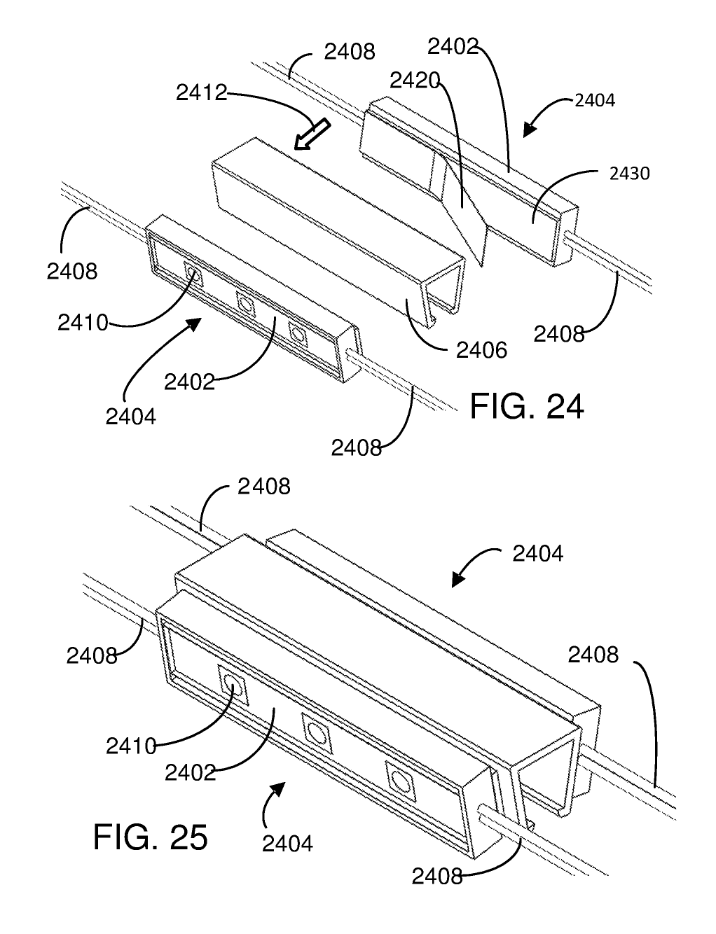

FIGS. 24-27 illustrate an LED light assembly 2404 having a tape-on jaw 2406 enabling attachment of two LED light modules 2402 on opposing sides.

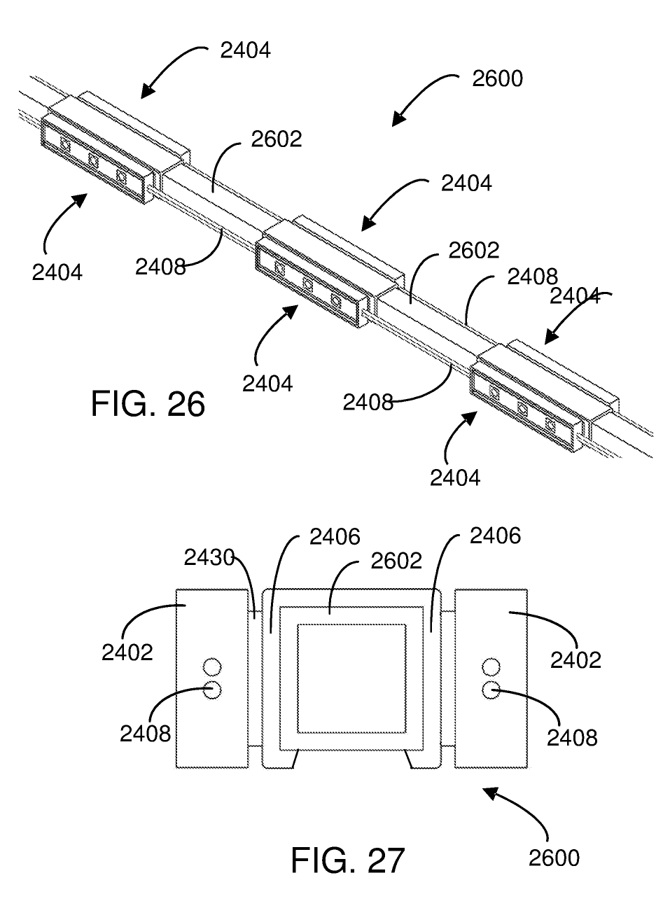

FIG. 24 is an isometric view of the assembly process for a two-sided LED mount 2404. Double-sided adhesive tape 2430 has one sticky side pre-attached to the back (i.e., the side opposite from the LEDs 2410) of LED light module 2402, with the opposite sticky side initially covered by a tape liner 2420. After manual removal of tape liner 2420 (this peeling-off operation is shown in progress in FIG. 24), LED mount 2404 may be moved (attachment motion 2412) to place jaw 2406 in contact with double-sided adhesive tape 2430, which has a sticky surface now exposed after removal of tape liner 2420. Each LED light module 2402 may comprise one or more LEDs 2410 with power supplied by LED wires 2408. The clamping function of jaws 2406 is shown in FIG. 26. FIG. 25 is an isometric view of the two-sided LED mount 2404 of FIG. 24 after completion of mounting two LED light modules 2402, one attached to each jaw 2406. As for LED light assemblies 500, 1300, and 2200, unidirectional or bidirectional illumination is possible if the two sets of LED light modules 2402 are wired separately. FIG. 26 is an isometric view of LED light assembly 2600 attached to a support element 2602. FIG. 27 is an end view of LED light assembly 2600.

Assembly Method for an LED Light Assembly with a Tape-On Mounting Adaptor

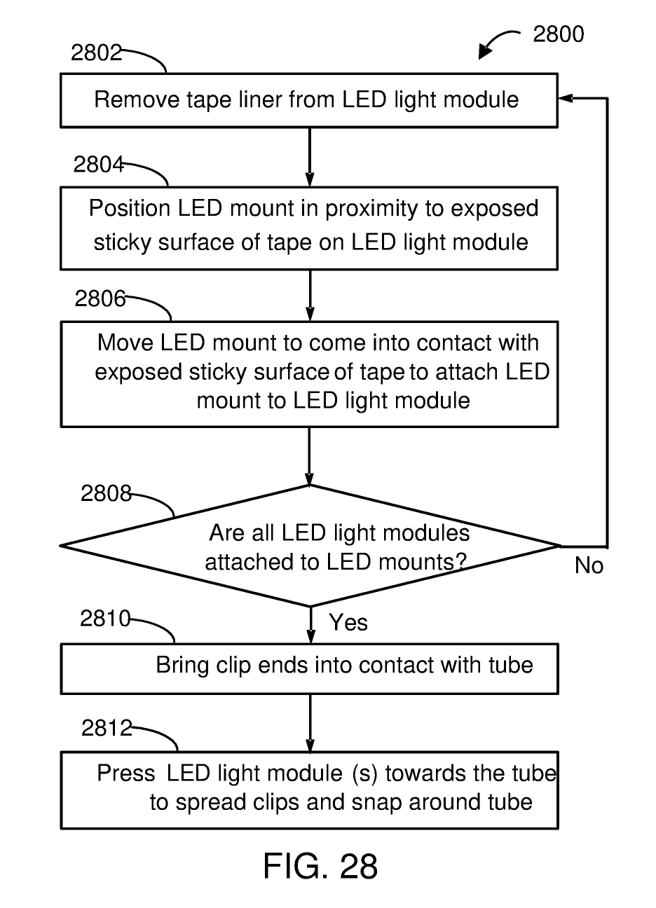

FIG. 28 is a flow chart of a method 2800 for construction of the LED light assembly of FIGS. 1-6. Method 2800 begins at block 2802, where the tape liner is removed from the double-sided adhesive tape on the back of an LED light module (see FIG. 1). Next, in block 2804, the LED mount is positioned with respect to the LED light module to ensure that after assembly the LED light module will be in the proper location when clamped to a support element. In block 2806, the LED mount is firmly attached (using the double-sided adhesive tape) to the LED light module by pressing together.

Decision block 2808 determines whether all of the LED light modules have been prepared for mounting by attachment of LED mounts. If “No”, then block 2802 is re-entered and the procedure in blocks 2802-2806 is repeated for the next LED light module in the string of LED light modules mutually interconnected by LED wires. If “Yes”, then block 2810 is entered and the mounting process onto a support element is repeated for each LED light module in blocks 2810 and 2812.

Assembly Method for an LED Light Assembly with a Horizontal Support Element

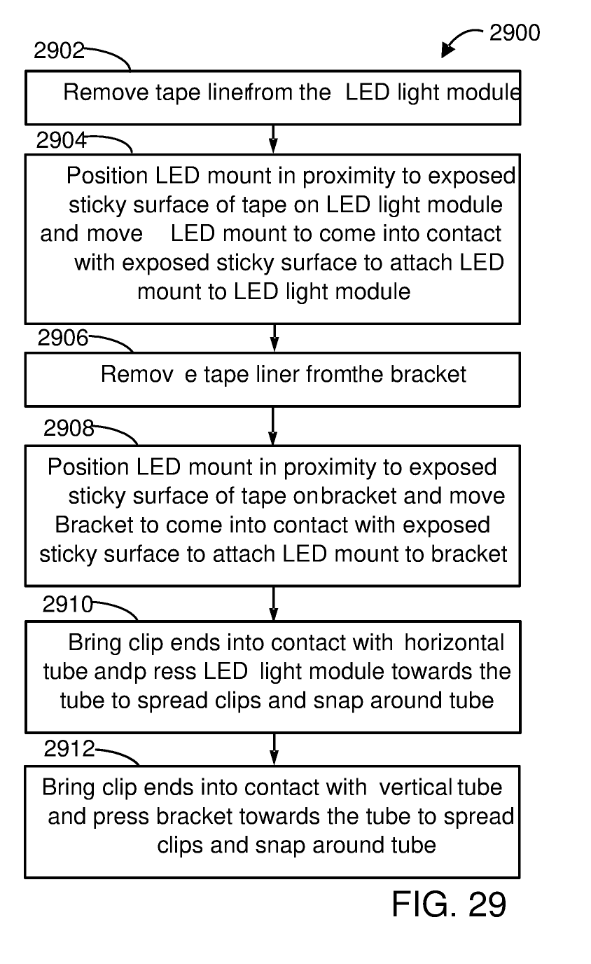

FIG. 29 is a flow chart of a method 2900 for construction of the LED light assembly of FIGS. 7-12. Method 2900 begins at block 2902, where the tape liner is removed from the double-sided adhesive tape on the back of the LED light module (see FIG. 17). Next, in block 2904, the LED mount is positioned with respect to the LED light module to ensure that after assembly the LED light module will be in the proper location when clamped to a horizontal support element. The LED mount is then firmly attached (using the double-sided adhesive tape) to the LED light module by pressing together.

In block 2906, the tape liner is removed from the bracket. Next, in block 2908, the LED mount is positioned with respect to the bracket to ensure that after assembly the LED light module will be in the proper location when clamped to a vertical support element. The LED mount is then firmly attached (using the double-sided adhesive tape) to the bracket by pressing together.

In block 2910 the jaw ends of one or more LED light modules are brought into contact with a horizontal support element and pressed to snap the jaws on the LED mount around the horizontal support element. Next, in block 2912 the jaw ends of one or brackets are brought onto contact with one or more vertical support elements and pressed to snap the jaws on the LED mount around the one or more vertical support elements.

Assembly Method for an LED Light Assembly with Interlocking Jaws

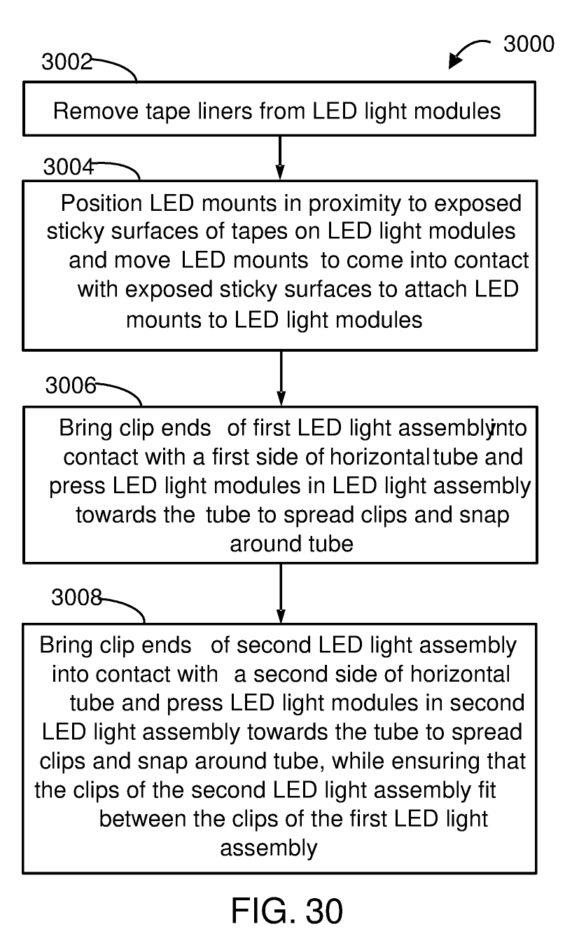

FIG. 30 is a flow chart of a method 3000 for construction of the LED light assembly of FIGS. 20-23.

Method 3000 begins at block 3002, where the tape liners are removed from the double-sided adhesive tapes on the backs of one or more LED light modules. Next, in block 3004 the LED mounts are positioned with respect to the LED light modules to ensure that after assembly the LED light modules will be in the proper locations when clamped to a horizontal support element. The LED mounts are then firmly attached (using the double-sided adhesive tapes) to the LED light modules by pressing together.

In block 3006 the jaw ends of one or more LED light modules in a first LED light assembly are brought into contact with a horizontal support element and pressed to snap the jaws on the LED mount around the horizontal support element—at this point the assembly appears as shown in FIG. 22. Next, in block 3008 the jaw ends in a second LED light assembly are brought into contact with the same horizontal support element but now from the opposite side of the support element, where the individual legs of the jaws are fitted between the individual legs of the jaws on the first LED light assembly—at this point the assembly appears as shown in FIG. 23.

In the embodiments shown, the support element was illustrated with a square cross-sectional shape with jaws shaped correspondingly. Other cross-sectional support element shapes fall within the scope of the invention, including: square, triangular, rectangular, pentagonal, hexagonal, “I”-shaped, “L”-shaped, and round. Jaws may be designed within the scope of the invention to provide secure mounting to these various support element shapes. Embodiments provide clamping to horizontal, vertical or both horizontal and vertical support elements, however embodiments may provide clamping to support elements in various spatial orientations. Jaws may be designed to accommodate various sizes of support element.

While the foregoing describes a preferred embodiment of the present invention, one skilled in the art will appreciate that various changes, substitutions and alterations may be made without departing from the scope of the invention. Although the present invention and its advantages have been described in detail, it should be understood that various changes, substitutions and alterations may be made herein without departing from the scope of the invention as defined by the appended claims. LED modules can be attached on any surface of the adapter, and on multiple surfaces to provide light output in different directions. Either a single mounting adapter or multiple mounting adapters can be attached to a single support. The mounting adapter can be of any length and the adapter length of the adapter will vary with the implementation. For example, the length of the adapters can be similar to the length of the LED module or similar to the length of the support. The long axis of the LED light module can be parallel to the long axis of the mounting adapter, or the axes can be perpendicular, or any orientation in between. The long axis of the LED module could therefore be at any orientation relative to the long axis of the support element. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1-8. (canceled)

9. An LED light assembly, comprising:
an LED light module;
a mounting adaptor, upon which the LED light module is mounted, operable for mounting the LED light module onto a first support element, the mounting adaptor including:
a first attachment surface, to which the LED light module is attached;
a clamp, operable to attach the mounting adaptor to the first support element, the clamp comprising:
a first jaw; and
a second jaw oriented approximately parallel to the first jaw and extending in the same direction as the first jaw;
in which the clamp is operable to snap onto the first support element.

10. The LED light assembly of claim 9, in which each of the first jaw and the second jaw include an inward-facing catch, the inward-facing catches being operable to attach the mounting adaptor to the first support element.

11. The LED light assembly of claim 10, in which the inward-facing catches have beveled leads to facilitate mounting of the mounting adaptor to the first support element.

12. The LED light assembly of claim 9, in which the jaws are substantially perpendicular to the attachment surface.

13. The LED light assembly of claim 10, in which the first and second jaws are operable to mount onto the first support element having a cross-sectional shape selected from the group consisting of: square, triangular, rectangular, pentagonal, hexagonal, “I”-shaped, “L”-shaped, and round.

14. The LED light assembly of claim 9, further comprising a second clamp-attached to the mounting adapter.

15. The LED light assembly of claim 9, further comprising a second LED light module mounted onto a second mounting adaptor, the second LED light module being electrically connected to the LED light module.

16. The LED light assembly of claim 9, in which the mounting adapter further comprises a tab to facilitate spreading the jaws to remove the mounting adapter from the support element.

17. The LED light assembly of claim 9, in which the jaws have a non-zero “toe-in” angle.

18. A method for mounting an LED light module onto a support element, the method comprising:
attaching an LED light module to an attachment surface of an LED mounting adaptor, the mounting adaptor including a clamp; and
snapping the clamp of the LED mounting adapter onto the support element to attach the LED light module to the support element.

19. The method of claim 18, in which attaching an LED light module to an attachment surface of the LED mounting adaptor comprises attaching an LED light module to an attachment surface of a mounting adaptor using double-sided adhesive tape.

20. The method of claim 18, in which:
the clamp includes jaws having inward facing catches on the distal edges of the jaws;
in snapping the clamp of the LED mounting adapter onto the support element to attach the LED light module to the support element,
the method further comprising:
spreading the jaws apart;
moving the jaws such that the support element is inserted between the jaws and the distal edges of the jaws extend beyond the support element; and
allowing the jaws to move together, whereby the catches attach the LED light module to the support element.

21. The method of claim 18, further comprising attaching a second clamp to the LED mounting adapter for attaching the LED mount to a second support element having an orientation different from that of the support element.

22. (canceled)

23. The method of claim 18, further comprising:
attaching a second LED light module to an attachment surface of a second LED mounting adaptor; and
snapping the clamp of the second LED mounting adapter onto the support element to attach the second LED light module to the support element.

24. The method of claim 23 further comprising electrically connecting the second LED light module and the LED light module to a power supply.

25. An LED mounting adaptor, upon which an LED light module can be mounted, and operable for mounting the LED light module onto a first support element, the mounting adaptor including:
a first attachment surface, to which the LED light module is attached;
a clamp, operable to attach the mounting adaptor to the first support element, the clamp comprising:
a first jaw;
a second jaw oriented approximately parallel to the first jaw and extending in the same direction as the first jaw; and
a tab attached to the distal end of at least one jaw for opening the jaw;
in which the clamp is operable to snap onto the first support element.

26. The LED mounting adapter of claim 25 in which at least one of the jaws include a projection extending in a direction normal to the jaw, the projection positioned to trap the support element within the jaws.

27. The LED mounting adapter of claim 25 in which the tab includes an angled surface that provides an opening force when the mounting adapter is pushed onto the support element.

28. The LED mounting adapter of claim 25 in which the LED mounting adapter comprises a polymer.

29-31. (canceled)

32. The LED light assembly of claim 9, further comprising an adhesive adhering the LED light module to the mounting adapter.

33. The method of claim 18, in which attaching the LED light module to the attachment surface of the LED mounting adaptor comprising attaching the LED light module to the attachment surface of the LED mounting adaptor using an adhesive.

34. The LED mounting adapter of claim 25 in which the LED light module is attached to the first attachment surface using an adhesive.
